(19) United States
(12) Patent Application Publication
(10) Pub. No.: US 2010/0139554 A1
(43) Pub. Date: Jun. 10, 2010

(54) METHODS AND APPARATUS FOR MAKING GALLIUM NITRIDE AND GALLIUM ALUMINUM NITRIDE THIN FILMS

(75) Inventors: Morteza Farnia, Campbell, CA (US); Mehran Moalem, Cupertino, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/633,279

(22) Filed: Dec. 8, 2009

Related U.S. Application Data
(60) Provisional application No. 61/120,840, filed on Dec. 8, 2008.

(51) Int. Cl. C30B 25/10

(52) U.S. Cl. 117/103; 134/1.2

(57) ABSTRACT

Methods and apparatus for forming gallium nitride and gallium aluminum nitride films, such as gallium nitride and gallium aluminum nitride epitaxial layers on a substrate are provided, including providing a substrate; and exposing the substrate to gallium vapor and an NH₃ plasma so as to form a gallium nitride epitaxial layer on at least a portion of the substrate.

### CROSS-REFERENCE TO RELATED APPLICATIONS

This application claims benefit of U.S. provisional patent application Ser. No. 61/120,840, filed Dec. 8, 2008, which is herein incorporated by reference.

### BACKGROUND OF THE INVENTION

1. Field of the Invention

Embodiments of the present invention are generally related to the manufacture of electronic devices, and more particularly to the formation of gallium nitride and gallium aluminum nitride films on substrates.

2. Description of the Related Art

Group-III nitride semiconductors are finding greater importance in the development and fabrication of short wavelength light emitting diodes (LEDs), laser diodes (LDs), and electronic devices including high power, high frequency, and high temperature transistors and integrated circuits. Several technologies have been developed to grow Group III-V semiconductors, such as metal organic chemical vapor deposition (MOCVD), molecular beam epitaxy (MBE) and hydride vapor phase epitaxy (HVPE).

HVPE processes offers several advantages, such as high growth rate, simplicity, and low manufacturing cost compared to other conventional techniques. HVPE processes for growing Group III-V are generally performed in a reactor having a temperature controlled environment to assure the stability of a Group III metal used in the process. Group III metals provided by a Group III source, such as a gallium (Ga) metal source, in the reactor reacts with a halide, such as hydrogen chloride (HCl) gas, forming Group III halide vapor. A nitrogen containing precursor, such as ammonia (NH₃), is subsequently transported by a separate gas line to a reaction zone in the reactor where it is heated and mixes with the Group III halide vapor, such as GaCl. A carrier gas is used to carry Group III halide and Group V vapor towards the substrate within the reactor. The mixed Group III halide, such as GaCl, and nitrogen containing precursor, such as ammonia (NH₃), carried by the carrier gas is subsequently eptaxially grown into a Group III-V layer (GaN) on the substrate surface.

MOCVD processes are generally performed in a reactor having a temperature controlled environment to assure the stability of a first precursor gas which contains at least one element from Group III, such as gallium (Ga). A second precursor gas, such as ammonia (NH₃), provides the nitrogen needed to form a Group III-nitride. The two precursor gases are injected into a processing zone within the reactor where they mix and move towards a heated substrate in the processing zone. A carrier gas may be used to assist in the transport of the precursor gases towards the substrate. The precursors react at the surface of the heated substrate to form a Group III-nitride layer, such as GaN, on the substrate surface.

As the demand for LEDs, LDs, transistors, and integrated circuits increases, the efficiency of depositing the Group-III metal nitride takes on greater importance. Therefore, there is a need in the art for an improved deposition methods and apparatus.

### SUMMARY OF THE INVENTION

In some aspects of the invention a method of forming a gallium nitride epitaxial layer on a substrate is provided, including providing a substrate and exposing the substrate to a mixture of NH₃ and one or more gallium compounds selected from the group consisting of gallium sesquichloride and gallium hydride so as to form the gallium nitride epitaxial layer on at least a portion of the substrate.

In some aspects of the invention a method of forming a gallium nitride epitaxial layer on a substrate is provided, including providing a substrate and exposing the substrate to gallium vapor and an NH₃ plasma so as to form the gallium nitride epitaxial layer on at least a portion of the substrate.

In some aspects of the invention a method of forming a gallium aluminum nitride epitaxial layer on a substrate is provided, including providing a substrate and exposing the substrate to: 1) an aluminum compound selected from the group consisting of aluminum hydride and aluminum sesquichloride, 2) a gallium compound selected from the group consisting of gallium sesquichloride and gallium hydride, and 3) ammonia plasma so as to form a gallium aluminum nitride epitaxial layer on at least a portion of the substrate.

In some aspects of the invention a method of cleaning a deposition chamber is provided, including providing a deposition chamber having one or more of a gallium nitride film and a gallium aluminum nitride film; exposing the chamber to a hydrogen plasma whereby a portion of the gallium nitride or gallium aluminum nitride is removed from surfaces of the chamber; and exhausting the deposition chamber.

Numerous other aspects are provided in accordance with these and other aspects of the invention. Other features and aspects of the present invention will become more fully apparent from the following detailed description, the appended claims and the accompanying drawings.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic depiction of an apparatus of the present invention for forming a gallium nitride film on a substrate;

FIG. 2 is a flow chart depicting a method of the present invention for forming a gallium nitride film on a substrate;

FIG. 3 is a flow chart depicting another method of the present invention for forming a gallium nitride film on a substrate;

FIG. 4 is a flow chart depicting a method of the present invention for forming a gallium aluminum nitride film on a substrate; and

FIG. 5 is a flow chart depicting a method of the present invention for cleaning a deposition chamber.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The following detailed examples depict one or more exemplary embodiments of the present invention. Although in some cases the document may imply that the invention may only be practiced in one way, it should be understood that many alternative embodiments are possible and that the specific details disclosed herein are merely provided as examples.

Thin films of gallium nitride and gallium aluminum nitride may be useful in the manufacture of light emitting diodes, or LEDs. Prior to the present invention, gallium nitride films have typically been made by exposing a substrate, typically sapphire, to trimethyl gallium and ammonia so as to form a layer of gallium nitride. A problem associated with such prior art methods is that the deposition rate of gallium nitride may be slower than is commercially desirable.

In addition, prior to the present invention, gallium nitride and gallium aluminum nitride films may typically have been cleaned from process chamber surfaces and chamber equipment using a Cl₂ or an HCl plasma. While chlorine and hydrogen chloride plasmas may be effective to clean the gallium nitride and gallium aluminum nitride films from the chamber and equipment, byproducts of the clean may include relatively high boiling point gallium chlorides, aluminum chlorides and ammonium chlorides. Such relatively high boiling point byproducts may typically require chamber exhaust conduits and pumps to be heated to temperatures of about 150° C. to prevent the byproducts from condensing in the conduits and pumps and clogging the same. A chamber clean which would obviate the need to heat the exhaust conduits and pumps to prevent byproduct condensation would be desirable.

The present invention provides methods and apparatus for making gallium nitride and gallium aluminum nitride films. These films may be grown epitaxially, or may simply be deposited on a substrate, and optionally annealed. For ease of reference, epitaxially grown layers and deposited layers may be referred to herein simply as deposited or formed layers, except where doing so would be inconsistent with a description of an apparatus or method. In addition, methods and apparatus are provided for cleaning process chambers which have gallium nitride and gallium aluminum nitride films which need to be removed.

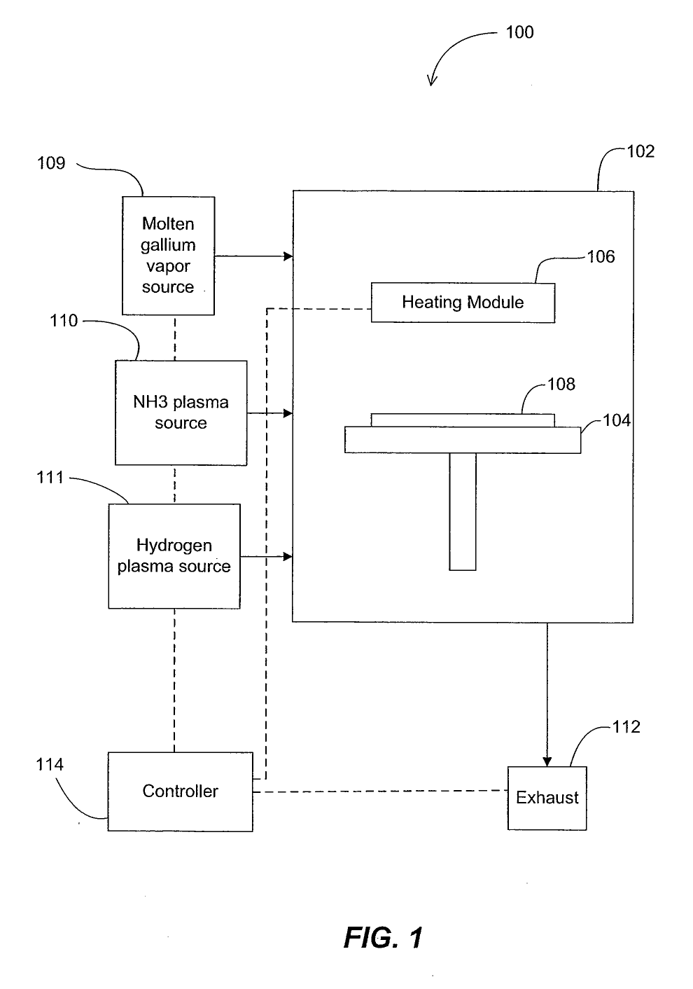

In one embodiment of the invention, a system is provided for depositing a gallium nitride film onto a substrate. FIG. 1 is a schematic diagram of an exemplary film formation system 100. With reference to FIG. 1, the system 100 may include a deposition chamber 102 that includes a substrate support 104 and at least one heating module 106. The substrate support 104 may be adapted to support a substrate 108 during film formation within the chamber 102, and the heating module 106 may be adapted to heat the substrate 108 during film formation within the deposition chamber 102. More than one heating module, and/or other heating module locations may be used. The heating module 106 may include, for example, a lamp array or any other suitable heating source and/or element.

The system 100 may also include a gallium vapor source 109, an NH₃ plasma source 110, a hydrogen plasma source 111 and an exhaust system 112 coupled to the deposition chamber 102. The system 100 may also include a controller 114 coupled to the deposition chamber 102, the gallium vapor source 109, the NH₃ plasma source 110, the hydrogen plasma source 111 and/or the exhaust system 112. The exhaust system 112 may include any suitable system for exhausting waste gasses, reaction products, or the like from the chamber 102, and may include one or more vacuum pumps.

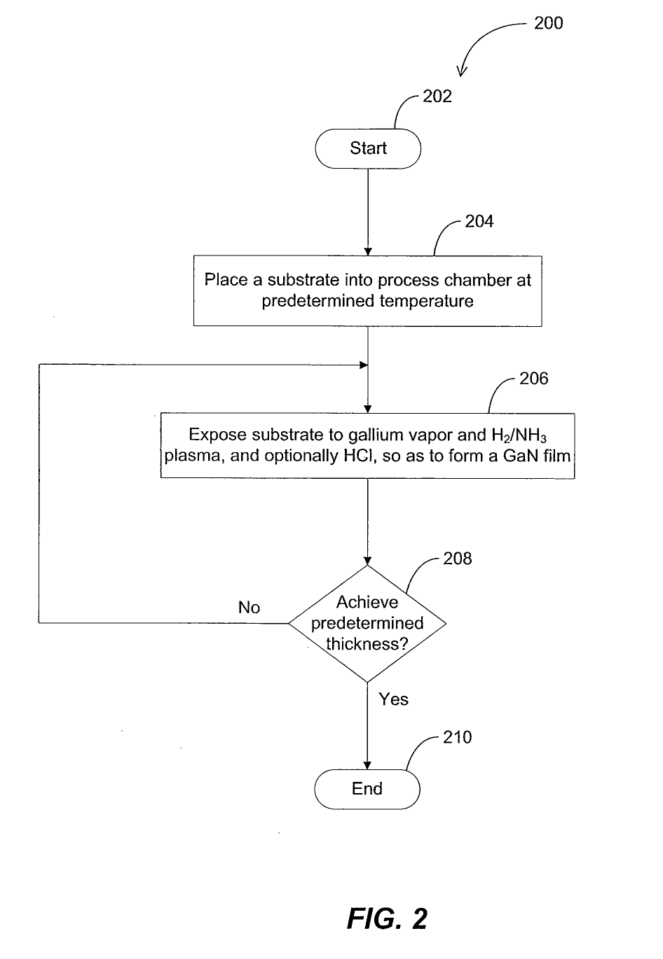

The controller 114 may include one or more microprocessors and/or microcontrollers, dedicated hardware, a combination the same, etc., that may be employed to control operation of the deposition chamber 102, the gallium vapor source 109, the NH₃ plasma source 110, the hydrogen plasma source 111 and/or the exhaust system 112. In at least one embodiment, the controller 114 may be adapted to employ computer program code for controlling operation of the system 100. For example, the controller 114 may perform or otherwise initiate one or more of the steps of any of the methods/processes described herein, including methods 200, 300, 400 and 500 of FIGS. 2-5. Any computer program code that performs and/or initiates such steps may be embodied as a computer program product. Each computer program product described herein may be carried by a medium readable by a computer (e.g., a carrier wave signal, a floppy disc, a compact disc, a DVD, a hard drive, a random access memory, etc.).

In another embodiment of the present invention, a gallium nitride film may be deposited or grown epitaxially on a substrate, such as a sapphire substrate. FIG. 2 is a flowchart depicting a method 200 of the present invention for depositing a gallium nitride film on a substrate. The method 200 begins in step 202. In step 204, a substrate is placed into a process chamber at a predetermined or selected temperature. In one embodiment, the temperature of the chamber is between about 800° C. and about 1,100° C., for example, about 1,000° C.

In step 206, the substrate is exposed to a gallium vapor and an NH₃ plasma under conditions suitable to form the gallium nitride film, such as, for example, an epitaxial layer. The pressure within the chamber may be, for example, between about 2 Torr and about 600 Torr, or about 90 Torr. Other suitable chamber temperatures and pressures may be used.

The NH₃ plasma may be created in the deposition chamber or may be created remotely and introduced into the deposition chamber.

Gallium vapor may be created by placing gallium into a vessel, such as a crucible, and heating the vessel to melt the gallium. The vessel may be heated to a temperature of from about 100° C. to about 250° C. In some embodiments nitrogen gas may be passed over the vessel containing the molten gallium at a pressure of about 1 Torr and pumped to the process chamber. The nitrogen may be flowed at a rate of about 200 standard cubic centimeters per minute (sccm). The gallium vapor may be drawn into the process chamber by a vacuum.

In step 208, a determination is made whether a thickness of the gallium nitride film has met a predetermined thickness standard. If the predetermined thickness standard has been achieved, the method 200 ends in step 210. If the predetermined thickness standard has not been achieved, the method loops back and the substrate continues to be exposed to the gallium vapor and the NH3 plasma.

In an alternative embodiment, the substrate may be exposed to the gallium vapor, the NH₃ plasma and one or more of hydrogen and hydrogen chloride. The hydrogen and/or the hydrogen chloride may increase the rate of deposition. While not wishing to be bound to any particular theory, the hydrogen chloride may help drive an equilibrium of gallium vapor, NH₃ plasma and a gallium nitride toward gallium nitride.

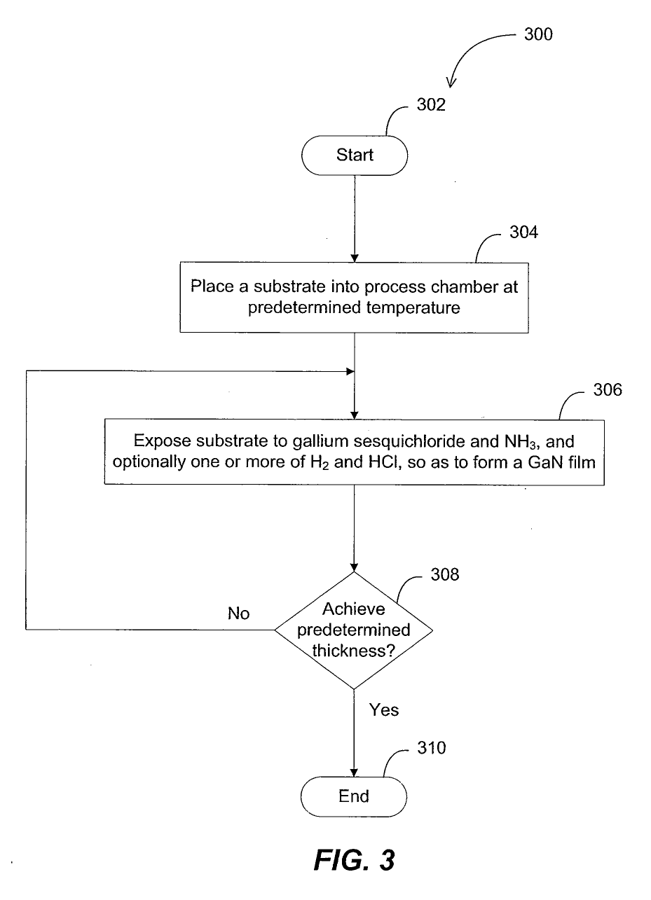

In another embodiment of the present invention, a gallium nitride film may be deposited on a substrate using a gallium sesquichloride precursor and/or a gallium hydride precursor. FIG. 3 is a flowchart depicting a method 300 of the present invention for forming a gallium nitride film on a substrate.

Method 300 begins in step 302. In step 304, a substrate is placed into a process chamber and brought to or maintained at a predetermined temperature. The temperature of the chamber is between about 700° C. and about 1,000° C. The pressure of the chamber may be between about 2 Torr and about 600 Torr, or about 90 Torr. Other suitable chamber temperatures and pressures may be used.

In step 306, the substrate is exposed to gallium sesquichloride and/or gallium hydride and to an ammonia plasma under conditions adapted to form a gallium nitride film, such as an epitaxial layer. Gallium sesquichloride may be one or more of GaHCl₂, GaH₂Cl, GaRCl₂ and GaR₂Cl, where R is an alkyl group. GaHCl₂, GaH₂Cl, GaRCl₂ and GaR₂Cl may be in the form of one or more of monomers, dimers, and trimers.

In an alternative embodiment, the substrate may be exposed to one or more of hydrogen and hydrogen chloride while the substrate is being exposed to gallium sesquichloride and/or gallium hydride and ammonia plasma.

In step 308, a determination is made whether a thickness of the gallium nitride film has met a predetermined thickness standard. If the predetermined thickness standard has been achieved, the method 300 ends in step 310. If the predetermined thickness standard has not been achieved, the method loops back and the substrate continues to be exposed to the gallium sesquichloride and/or gallium hydride and the NH₃ plasma.

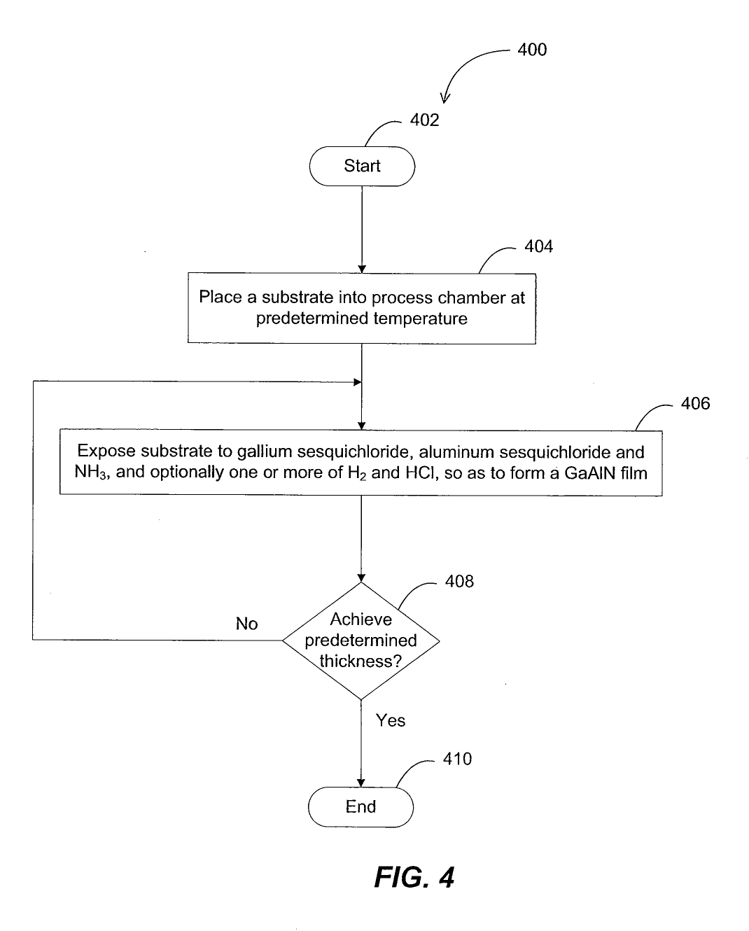

In another embodiment, a gallium aluminum nitride film may be deposited or grown on a substrate using a gallium sesquichloride and/or a gallium hydride, and an aluminum sesquichloride and/or an aluminum hydride precursor. FIG. 4 is a flowchart depicting a method 400 of the present invention for forming a gallium aluminum nitride film on a substrate.

Method 400 begins in step 402. In step 404, a substrate is placed into a process chamber at a predetermined temperature. The temperature of the chamber is between about 700° C. and about 1,000° C., or about 800° C. to about 900° C. The pressure of the chamber may be between about 2 Torr and about 600 Torr, or about 90 Torr. Other suitable chamber temperatures and pressures may be used.

In step 406, the substrate is exposed to one or more of gallium sesquichloride and gallium hydride, one or more of aluminum sesquichloride and aluminum hydride, and to ammonia plasma under conditions selected to form a gallium aluminum nitride film, such as an epitaxial gallium aluminum hydride film. Aluminum sesquichloride may be one or more of AlHCl₂, AlH₂Cl, AlRCl₂ and AlR₂Cl, where R is an alkyl group. In one embodiment, the alkyl group may have the general formula CₙH₂ₙ₊₁ where n is between 1 and 10. Examples include but are not limited to methyl, ethyl, n-propyl, n-butyl, n-pentyl, n-hexyl, n-heptyl, n-octyl, n-nonyl, and n-decyl. Other suitable alkyl groups include branched chain structures. AlHCl₂, AlH₂Cl, AlRCl₂ and AlR₂Cl may be in the form of one or more of monomers, dimers, and trimers.

In an alternative embodiment, the substrate may be exposed to one or more of hydrogen and hydrogen chloride while the substrate is being exposed to the gallium sesquichloride and/or gallium hydride, the aluminum sesquichloride and/or aluminum hydride and the NH₃ plasma.

In step 408, a determination is made whether a thickness of the gallium aluminum nitride film has met a predetermined thickness standard. If the predetermined thickness standard has been achieved, the method 400 ends in step 410. If the predetermined thickness standard has not been achieved, the method loops back and the substrate continues to be exposed to one or more of gallium sesquichloride and gallium hydride, one or more of aluminum sesquichloride and aluminum hydride, and to ammonia plasma.

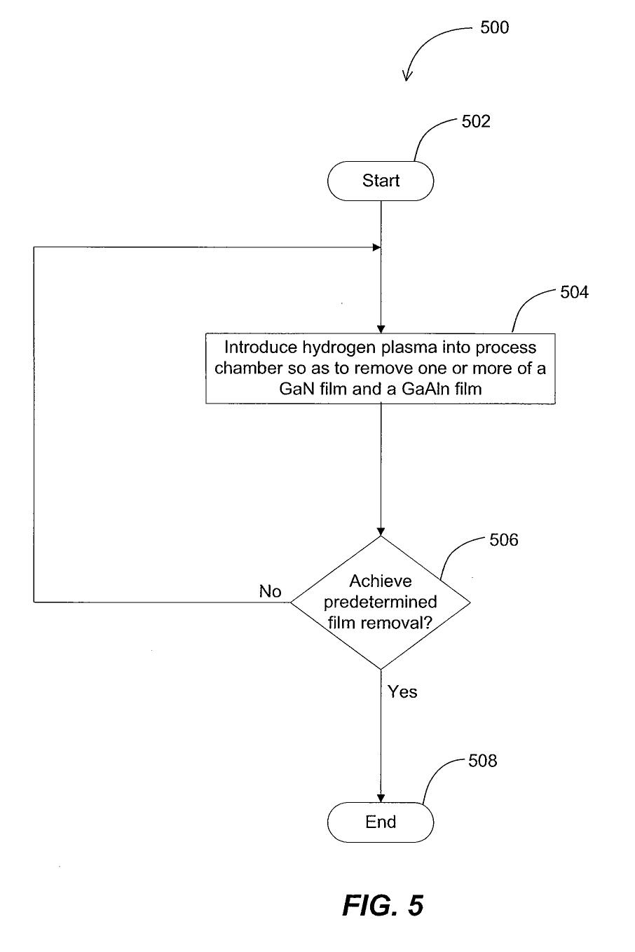

In another embodiment of the present invention, a method for cleaning one or more of gallium nitride and gallium aluminum nitride films from a process chamber is provided. FIG. 5 is a flow chart depicting method 500 for cleaning gallium nitride and gallium aluminum nitride films from process chambers.

Method 500 begins in step 502. In step 504, a hydrogen plasma is introduced into a process chamber which has one or more films of gallium nitride and/or gallium aluminum nitride. The hydrogen plasma may be made in-situ in the chamber, or may be made remotely and drawn or pumped into the chamber. While not wishing to be bound to any particular theory, in the process of removing the gallium nitride and/or the gallium aluminum nitride films from the chamber and chamber equipment, the hydrogen plasma and the gallium nitride and/or gallium aluminum nitride may form byproducts such as GaH₃, AlH₃ and NH₃, which may easily be removed from the process chamber through exhaust conduits and pump systems without the byproducts condensing in the exhaust conduits and pumps. The hydrogen plasma/gallium nitride/gallium aluminum nitride reaction byproducts may have relatively low boiling points which may not require supplementary heating of the exhaust conduits and pumps to avoid condensation of the byproducts and clogging of the pumps and conduits. Method 500 may employ chamber temperatures of about 800° C., and chamber pressures of between about 0.5 and 100 Torr or about 1 or about 2 Torr. Other suitable chamber temperatures and pressures may be used.

In step 506, a determination is made whether a predetermined film removal from the chamber has been achieved. If the predetermined film removal has been achieved, the method 500 ends in step 508. If the predetermined film removal has not been achieved, the method loops back and the chamber is exposed to the hydrogen plasma so as to remove one or more of a GaN film and a GaAlN film.

While the foregoing is directed to embodiments of the present invention, other and further embodiments of the invention may be devised without departing from the basic scope thereof, and the scope thereof is determined by the claims that follow.

1. A method of forming a gallium nitride epitaxial layer on a substrate comprising:
positioning a substrate in a process chamber; and
exposing the substrate to a mixture of NH₃ plasma and one or more gallium compounds selected from the group consisting of gallium sesquichloride and gallium hydride so as to form the gallium nitride epitaxial layer on at least a portion of the substrate.

2. The method of claim 1, wherein the gallium sesquichloride is selected from the group comprising GaHCl₂, GaH₂Cl, GaRCl₂, GaR₂Cl, monomers thereof, dimers thereof, trimers thereof, and combinations thereof, where R is an alkyl group.

3. The method of claim 1, wherein a temperature of the process chamber is between about 700° C. and about 1,000° C.

4. The method of claim 3, wherein a pressure within the process chamber is between about 2 Torr and about 600 Torr.

5. The method of claim 4, wherein the pressure is about 90 Torr

6. The method of claim 1, wherein the mixture further comprises one or more of hydrogen and hydrogen chloride gas.

7. The method of claim 1, wherein the NH₃ plasma is formed remotely and introduced into the deposition chamber.

8. The method of claim 1, wherein the NH₃ plasma is formed in-situ.

9. A method of forming a gallium aluminum nitride epitaxial layer on a substrate comprising:
positioning a substrate in a process chamber; and
exposing the substrate to 1) an aluminum compound selected from the group consisting of aluminum sesquichloride and aluminum hydride; 2) a gallium compound selected from the group consisting of gallium sesquichloride and gallium hydride; and 3) ammonia plasma so as to form a gallium aluminum nitride epitaxial layer on at least a portion of the substrate.

10. The method of claim 9, wherein the aluminum sesquichloride may be selected from the group comprising AlHCl₂, AlH₂Cl, AlRCl₂, AlR₂Cl, monomers thereof, dimers thereof, trimers thereof, and combinations thereof, where R is an alkyl group.

11. The method of claim 10, wherein the gallium sesquichloride is selected from the group comprising GaHCl₂, GaH₂Cl, GaRCl₂, GaR₂Cl, monomers thereof, dimers thereof, trimers thereof, and combinations thereof, where R is an alkyl group.

12. The method of claim 9, wherein exposing the substrate further comprises exposing the substrate to one or more of hydrogen and hydrogen chloride while the substrate is being exposed to the gallium sesquichloride and/or gallium hydride, the aluminum sesquichloride and/or aluminum hydride and the NH₃ plasma.

13. The method of claim 9, wherein a temperature of the process chamber is between about 700° C. and about 1,000° C. and a pressure within the process chamber is between about 2 Torr and about 600 Torr.

14. The method of claim 14, wherein the temperature of the process chamber is between about 800° C. to about 900° C. and the process chamber is about 90 Torr.

15. The method of claim 14, further comprising:
exposing the chamber to a hydrogen plasma whereby a portion of the gallium aluminum nitride layer is removed from surfaces of the process chamber; and
exhausting the deposition chamber.

16. A method of cleaning a process chamber comprising:
providing a process chamber having one or more of a gallium nitride film and a gallium aluminum nitride film deposited on surfaces of the process chamber;
exposing the chamber to a hydrogen plasma whereby a portion of the gallium nitride or gallium aluminum nitride is removed from surfaces of the process chamber; and
exhausting the deposition chamber.

17. The method of claim 16, wherein the NH₃ plasma is formed remotely and introduced into the deposition chamber

18. The method of claim 16, wherein the NH₃ plasma is formed in-situ.

19. The method of claim 16, wherein the chamber is heated to a chamber temperature of about 800° C. and maintained at a pressure within the chamber between about 0.5 Torr and about 100 Torr.

20. The method of claim 19, wherein the pressure within the chamber is between about 1 Torr and about 2 Torr.
